(19) United States
(12) Patent Application Publication
(10) Pub. No.: US 2012/0037229 A1
(43) Pub. Date: Feb. 16, 2012

(54) PHOTOVOLTAIC GLASS LAMINATED ARTICLES AND LAYERED ARTICLES

(76) Inventors: David Francis Dawson-Elli, Elmira, NY (US); Steven Edward DeMartino, Painted Post, NY (US); Laura L. Hluck, Painted Post, NY (US)

(21) Appl. No.: 12/531,203

(22) PCT Filed: May 29, 2009
(86) PCT No.: PCT/US09/03295

§ 371 Date: Sep. 14, 2009

Related U.S. Application Data
(62) Division of application No. 61/057,344, filed on May 30, 2008.

(51) Int. Cl. H01L 31/0248; H01L 31/0272

(52) U.S. Cl. 136/260; 136/252; 136/265; 136/261

(57) ABSTRACT

Laminated articles and layered articles, for example, low alkali glass and/or low sodium laminated articles and layered articles useful for, for example, photovoltaic devices are described.

This patent application claims the benefit of priority to US Provisional Patent Application 61/057,344 filed on May 30, 2008.

### BACKGROUND

1. Field

Embodiments of the invention relate to laminated articles and layered articles and more particularly to low alkali glass and/or low sodium laminated articles and layered articles useful for, for example, photovoltaic devices.

2. Technical Background

The management and utilization of natural light is a consideration in photovoltaic devices, for example, how to maximize the efficiency of the photovoltaic device.

Photovoltaic devices must meet several safety codes and are subject to mechanical strength tests, for example, debris impact tests and post-breakage wind cycling. Photovoltaic devices can benefit from increased mechanical strength, for example, in order to withstand environmental conditions.

Functional materials for photovoltaic applications are typically applied to soda lime glass substrates. In some applications, the substrates are often coated with a barrier layer in order to minimize alkali, for example, sodium diffusion from the substrate into the functional materials. However, any breaks in the barrier layer, for example, scratches can allow sodium or alkalis to enter the functional material, which depending on the composition of the functional material, can compromise the utility of the functional material. Defects in the soda lime glass, for example, bubbles, scratches, inclusions can also compromise the utility of the functional material.

Glass strength can depend on exposure temperatures, aspect ratio, plate size, stiffness and load duration. Laminated glass can be made with annealed, heat strengthened, and/or fully tempered for additional benefits, such as resistance to increased wind loading, increased impact resistance or resistance to thermal stress.

It would be advantageous to have laminated articles and layered articles in which alkali diffusion and/or sodium diffusion can be minimized or estimated or controlled and where mechanical strength can be maximized.

### SUMMARY

Laminated articles and layered articles address one or more of the above-mentioned disadvantages of conventional laminated articles and layered articles and provide one or more of the following advantages: minimizing or estimating or controlling alkali diffusion and/or sodium diffusion into the functional material from the glass, reduction of defects in the glass, increased clarity, and minimized weight.

One embodiment is an article comprising:

a glass layer having a strain point of 500° C. or more;

a photovoltaic functional material disposed on the glass layer;

a substrate comprising a glass, a polymer, or a combination thereof, and having a thickness greater than that of the glass layer; and

a laminate layer disposed between the substrate and either the glass layer or the photovoltaic functional material.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1 is a schematic of an article according to one embodiment.

FIG. 2 is a schematic of an article according to one embodiment.

FIG. 3 is a schematic of an article according to one embodiment.

### DETAILED DESCRIPTION

Reference will now be made in detail to various embodiments of the invention, examples of which are illustrated in the accompanying drawings. Wherever possible, the same reference numbers will be used throughout the drawings to refer to the same or like parts.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module. Photovoltaic device can describe either a cell, a module, or both.

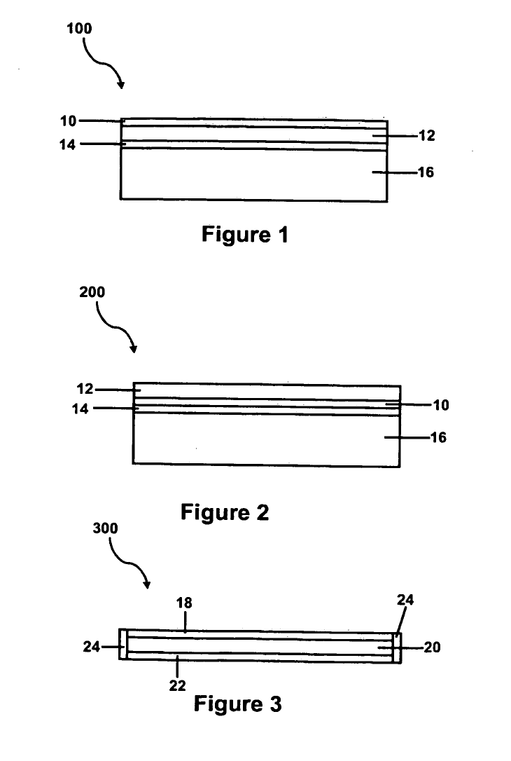

One embodiment, as shown in FIG. 1 and FIG. 2 is an article 100 and 200, respectively, comprising:

a glass layer 12 having a strain point of 500° C. or more;

a photovoltaic functional material 10 disposed on the glass layer;

a substrate 16 comprising a glass, a polymer, or a combination thereof, and having a thickness greater than that of the glass layer; and

a laminate layer 14 disposed between the substrate and either the glass layer or the photovoltaic functional material.

According to some embodiments, the glass layer has a thickness of 4.0 mm or less, for example, 3.5 mm or less, for example, 3.2 mm or less, for example, 3.0 mm or less, for example, 2.5 mm or less, for example, 2.0 mm or less, for example, 1.9 mm or less, for example, 1.8 mm or less, for example, 1.5 mm or less, for example, 1.1 mm or less, for example, 0.5 mm to 2.0 mm, for example, 0.5 mm to 1.1 mm, for example, 0.7 mm to 1.1 mm. Although these are exemplary thicknesses, the glass layer can have a thickness of any numerical value including decimal places in the range of from 0.1 mm up to and including 4.0 mm.

The glass layer, in one embodiment, is rollable. The glass, in one embodiment, is down-drawable. The glass can be slot drawn or fusion drawn, for example. According to another embodiment the glass can be float formed.

The properties of the glass layer, for example, the formability, CTE, strain point will depend on the composition of the glass.

In one embodiment, the glass layer has a strain point of 500° C. or more, for example, 540° C. or more, or for example, 500° C. to 600° C.

The glass layer can have a relatively low coefficient of thermal expansion (CTE), for example, 50×10⁻⁷/° C. or less, for example, 35×10⁻⁷/° C. or less. According to one embodiment, the glass layer has a CTE of 20×10⁻⁷/° C. to 50×10⁻⁷/° C., for example, 20×10⁻⁷/° C. to 35×10⁻⁷/° C. In one embodiment, the coefficient of thermal expansion of the glass layer is in the range of from 30×10⁻⁷/° C. to 90×10⁻⁷/° C. In some embodiments, the glass has a coefficient of thermal expansion of 50×10⁻⁷ or greater, for example, 60×10⁻⁷ or greater, for example, 70×10⁻⁷ or greater, for example, 80×10⁻⁷ or greater. In one embodiment, the glass has a strain point of from 50×10⁻⁷ to 90×10⁻⁷.

In one embodiment, the photovoltaic functional material comprises copper indium gallium diselenide (CIGS). In one embodiment, the photovoltaic functional material comprises copper indium gallium diselenide (GIGS) and the coefficient of thermal expansion of the glass layer is in the range of from 30×10⁻⁷/° C. to 90×10⁻⁷/° C.

In one embodiment, the coefficient of thermal expansion of the glass layer is in the range of from 60×10⁻⁷/° C. to 90×10⁻⁷/° C.

In one embodiment, the photovoltaic functional material comprises cadmium telluride. In one embodiment, the photovoltaic functional material comprises cadmium telluride and the coefficient of thermal expansion of the glass layer is in the range of from 60×10⁻⁷/° C. to 90×10⁻⁷/° C.

In one embodiment, the coefficient of thermal expansion of the glass layer is in the range of from 30×10⁻⁷/° C. to 60×10⁻⁷/° C.

In one embodiment, the glass layer is transparent.

The laminate layer can comprise a material selected from polyvinyl butyral, a UV curable resin, a thermoplastic, a thermoplastic ionoplast, polycarbonate, polyurethane, a UV curable polymer, silicone, and combinations thereof in some embodiments.

In one embodiment, the photovoltaic functional material comprises silicon. The silicon can be crystalline, nanocrystalline, amorphous, or combinations thereof.

In one embodiment, the substrate is transparent.

Another embodiment is an article comprising:

a transparent glass layer having an alkali oxide content of 10 percent by weight or less, wherein the transparent glass layer has thickness of from 0.5 mm to 4 mm;

a photovoltaic functional material disposed on the transparent glass layer;

a substrate comprising a glass, a polymer, or a combination thereof, and having a thickness greater than that of the transparent glass layer; and

a laminate layer comprising a material selected from polyvinyl butyral, a UV curable resin, a thermoplastic, a thermoplastic ionoplast, polycarbonate, polyurethane, a UV curable polymer, silicone, and combinations thereof disposed between the substrate and either the transparent glass layer or the photovoltaic functional material.

Another embodiment is an article comprising:

a transparent glass layer having a sodium oxide content of 10 percent by weight or less, wherein the transparent glass layer has thickness of from 0.5 mm to 4 mm;

a photovoltaic functional material disposed on the transparent glass layer;

a substrate comprising a glass, a polymer, or a combination thereof, and having a thickness greater than that of the transparent glass layer; and

a laminate layer comprising a material selected from polyvinyl butyral, a UV curable resin, a thermoplastic, a thermoplastic ionoplast, polycarbonate, polyurethane, a UV curable polymer, silicone, and combinations thereof disposed between the substrate and either the transparent glass layer or the photovoltaic functional material.

The substrate, according to one embodiment comprises a glass, a polymer, or a combination thereof. For instance, the substrate can comprise a material selected from float glass, fusion formable glass, soda lime glass, plastic, polycarbonate, and combinations thereof.

The photovoltaic functional material can comprise a single layer or multiple layers. The photovoltaic functional material can comprise multiple layers such as an electrode layer or layers, a counter electrode layer or layers, an ion conducting layer or layers. The layers, in some embodiments, can comprise solid inorganic materials.

The glass layer, according to one embodiment, comprises an alkali oxide content of 25 percent by weight, for example, 10 percent by weight or less, for example, 9 percent or less, for example, 8 percent or less, for example, 5 percent or less, for example, 0.5 percent or less. In one embodiment, the alkali oxide content is in the range of from 0.1 percent to 10 percent. Although these are exemplary alkali oxide contents, the glass layer can have alkali oxide contents of any numerical value including decimal places in the range of from 0 up to and including 10 percent by weight.

The glass layer, according to one embodiment, comprises a sodium oxide content of 10 percent by weight or less, for example, 9 percent or less, for example, 8 percent or less, for example, 5 percent or less, for example, 0.5 percent or less. In one embodiment, the sodium oxide content is in the range of from greater than 0 to 10 percent by weight, for example, 0.1 percent to 10 percent by weight. Although these are exemplary sodium oxide contents, the glass layer can have sodium oxide contents of any numerical value including decimal places in the range of from 0 up to and including 10 percent by weight.

According to some embodiments, the configuration of the article can be, for example, those described by FIG. 1 and FIG. 2, however, other configurations can be used in accordance with the invention. For example, the laminate layer, can be disposed between the substrate and either the glass layer or the photovoltaic functional material.

Another embodiment as shown in FIG. 3 is an article 300 comprising a glass layer 18 having a glass layer having a strain point of 500° C. or more; a photovoltaic functional material 20 disposed on the glass layer; and a protective layer 22 disposed on a surface of the photovoltaic material not in contact with the glass layer. The article, according to one embodiment, further comprises a seal material 24 joining the protective layer and the glass layer such that the combination of the protective layer, the glass layer, and the seal material together enclose the photovoltaic material. The seal material can be selected from a frit, a glass sheet, and a sputtered glass. The seal material in combination with the protective layer and the glass layer can minimize deleterious effects of exposing the photovoltaic functional material to the environment, for example, during shipping, manufacturing of a photovoltaic device, and/or in the final product such as photovoltaic cell or a photovoltaic module in a building in an on/off grid.

In this embodiment, the photovoltaic functional material can comprise multiple layers such as an electrode layer or layers, a counter electrode layer or layers, semiconductor materials, cadmium telluride, CIGS, amorphous silicon and/or crystalline silicon layer or layers. The layers, in some embodiments, can comprise solid inorganic materials.

In this embodiment, the glass layer can have a thickness of 4.0 mm or less, for example, 3.5 mm or less, for example, 3.2 mm or less, for example, 3.0 mm or less, for example, 2.5 mm or less, for example, 2.0 mm or less, for example, 1.9 mm or less, for example, 1.8 mm or less, for example, 1.5 mm or less, for example, 1.1 mm or less, for example, 0.5 mm to 2.0 mm, for example, 0.5 mm to 1.1 mm, for example, 0.7 mm to 1.1 mm. Although these are exemplary thicknesses, the glass layer can have a thickness of any numerical value including decimal places in the range of from 0.1 mm up to and including 4.0 mm.

The glass layer can have a relatively low coefficient of thermal expansion (CTE), for example, 50×10⁻⁷/° C. or less, for example, 35×10⁻⁷/° C. or less. According to one embodiment, the glass layer has a CTE of 20×10⁻⁷/° C. to 50×10⁻⁷/° C., for example, 20×10⁻⁷/° C. to 35×10⁻⁷/° C. In one embodiment, the coefficient of thermal expansion of the glass layer is in the range of from 30×10⁻⁷/° C. to 90×10⁻⁷/° C. In some embodiments, the glass has a coefficient of thermal expansion of 50×10⁻⁷ or greater, for example, 60×10⁻⁷ or greater, for example, 70×10⁻⁷ or greater, for example, 80×10⁻⁷ or greater. In one embodiment, the glass has a strain point of from 50×10⁻⁷ to 90×10⁻⁷.

The protective layer can provide chemical or mechanical durability. The protective layer can be a sputtered glass layer or a sheet of glass, for example, a transparent glass layer or sheet. The protective layer, according to some embodiments, has a thickness of 4.0 mm or less, for example, 3.5 mm or less, for example, 3.2 mm or less, for example, 3.0 mm or less, for example, 2.5 mm or less, for example, 2.0 mm or less, for example, 1.9 mm or less, for example, 1.8 mm or less, for example, 1.5 mm or less, for example, 1.1 mm or less, for example, 0.5 mm to 2.0 mm, for example, 0.5 mm to 1.1 mm, for example, 0.7 mm to 1.1 mm. Although these are exemplary thicknesses, the protective layer can have a thickness of any numerical value including decimal places in the range of from 0.1 mm up to and including 4.0 mm.

The protective layer can have a relatively low coefficient of thermal expansion (CTE), for example, 50×10⁻⁷/°C. or less, for example, 35×10⁻⁷/° C. or less. According to one embodiment, the protective layer has a CTE of 20×10⁻⁷/° C. to 50×10⁻⁷/° C., for example, 20×10⁻⁷/° C. to 35×10⁻⁷/° C. In one embodiment, the coefficient of thermal expansion of the protective layer is in the range of from 30×10⁻⁷/° C. to 90×10⁻⁷/° C.

The protective layer, in some embodiments, is transparent.

Laminating thin, low CTE, low alkali or low sodium glass coated with a material to thick soda lime glass enables process improvements and can minimize costs. Low CTE, low alkali and/or low sodium glass is durable, has increased clarity as compared to soda lime glass, and can be made with minimal defects, for example, in display glass applications for televisions.

According to one embodiment, 0.5 mm to 2.0 mm, for example, 0.7 mm to 1.1 mm low CTE, low alkali, for example, low sodium glass can be laminated to a less than 6 mm soda lime glass using a polyvinyl butyral laminate by one of a number of laminating processes. The soda lime glass could be annealed, heat strengthened (HS) and/or fully tempered (FT) depending on the strength required to meet relevant mechanical strength codes.

In this example, the soda lime glass provides a strength benefit in that it can be annealed, heat strengthened (typically 2× strength of annealed glass) and/or fully tempered (typically 4× strength of annealed glass) to provide additional mechanical strength. Low CTE low alkali, for example, low sodium glass is typically available only in annealed form, thus the substrate, in this example, the soda lime glass provides the increased strength of the laminated article.

The glass layer, according to the invention, provides one or more of the following advantages: low alkali and/or low sodium glass reduces the need for a barrier layer on soda lime glass in order to minimize sodium/alkali diffusion; low alkali or low sodium glass enhances the performance of organic or inorganic coating, for example, photovoltaic; low alkali or low sodium glass can be processed at high temperatures; low alkali or low sodium glass can be cut after coating. Thin low alkali glass or low sodium is light weight and minimizes the cost associated with a low CTE, low alkali or low sodium product.

Lamination can provide one or more of the following advantages, weather/natural disaster benefit, durability, design versatility, installation ease, and manufacturing ease. Lamination can be used to laminate a thin glass to various substrates.

The laminated articles and layered articles of the invention can be used, for example, and for photovoltaic devices both for roof top applications on buildings (commercial and residential), and on-off grid.

The laminated articles and layered articles can be incorporated as the outer, center or inner substrate or superstrate of a photovoltaic device, for example.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. An article comprising:
a glass layer having a strain point of 500° C. or more;
a photovoltaic functional material disposed on the glass layer;
a substrate comprising a glass, a polymer, or a combination thereof, and having a thickness greater than that of the glass layer; and
a laminate layer disposed between the substrate and either the glass layer or the photovoltaic functional material.

2. The article according to claim 1, wherein the glass layer has a thickness of 2.0 mm or less.

3. The article according to claim 1, wherein the glass layer has a strain point of 540° C. or more.

4. The article according to claim 1, wherein the coefficient of thermal expansion of the glass layer is in the range of from 30×10⁻⁷/° C. to 90×10⁻⁷/° C.

5. The article according to claim 1, wherein the glass layer has a sodium oxide content of 10 percent by weight or less.

6. The article according to claim 1, wherein the glass layer has a sodium oxide content of 1 percent by weight or less.

7. The article according to claim 1, wherein the glass layer has a sodium oxide content greater than 0 percent by weight.

8. The article according to claim 1, wherein glass layer has an alkali oxide content of 25 percent by weight or less.

9. The article according to claim 1, wherein the photovoltaic functional material comprises copper indium gallium diselenide.

10. The article according to claim 9, wherein the coefficient of thermal expansion of the glass layer is in the range of from 60×10⁻⁷/° C. to 90×10⁻⁷/° C.

11. The article according to claim 1, wherein the photovoltaic functional material comprises cadmium telluride.

12. The article according to claim 12, wherein the coefficient of thermal expansion of the glass layer is in the range of from 30×10⁻⁷/° C. to 60×10⁻⁷/° C.

13. The article according to claim 1, wherein the glass layer is transparent.

14. The article according to claim 1, wherein the substrate comprises a material selected from float glass, fusion formable glass, soda lime glass, plastic, and a polycarbonate.

15. The article according to claim 1, wherein the laminate layer comprises a material selected from polyvinyl butyral, a UV curable resin, a thermoplastic, a thermoplastic ionoplast, polycarbonate, polyurethane, a UV curable polymer, silicone, and combinations thereof.

16. The article according to claim 1, wherein the photovoltaic functional material comprises silicon.

17. The article according to claim 16, wherein the silicon is crystalline, nanocrystalline, amorphous, or combinations thereof.

18. The article according to claim 1, wherein the glass layer is fusion formable.

19. The article according to claim 1, wherein the photovoltaic functional material comprises multiple layers.

20. The article according to claim 1, wherein the substrate is transparent.

21. An article comprising:
a glass layer having a strain point of 500° C. or more;
a photovoltaic functional material disposed on the glass layer; and
a protective layer disposed on a surface of the photovoltaic functional material not in contact with the glass layer.
